(19) United States
(12) Patent Application Publication
(10) Pub. No.: US 2026/0223546 A1
(43) Pub. Date: Jul. 30, 2026

(54) DISPLAY PANEL AND DISPLAY DEVICE

(71) Applicant: Guangzhou China Star Optoelectronics Semiconductor Display Technology Co., LTd., Guangzhou (CN)

(72) Inventors: Xiaolin YAN, Guangzhou (CN); Weiran CAO, Guangzhou (CN); Jun ZHAO, Guangzhou (CN); Shan LI, Guangzhou (CN); Zhijiang ZHANG, Guangzhou (CN); Shuaiyi WANG, Guangzhou (CN)

(73) Assignee: Guangzhou China Star Optoelectronics Semiconductor Display Technology Co., LTd., Guangzhou (CN)

(21) Appl. No.: 19/224,784

(22) Filed: May 31, 2025

(30) Foreign Application Priority Data
Jan. 24, 2025 (CN) 202510122905.4

(51) Int. Cl. H10K 59/122; H10K 59/121

(52) U.S. Cl. CPC H10K 59/122; H10K 59/1213

(57) ABSTRACT

A display panel and a display device are provided. The display panel includes a first thin film transistor and a capacitor disposed in a region where a pixel opening is provided, the capacitor includes at least three electrode plates stacked and spaced apart, and a difference between a height of the first thin film transistor and a height of the capacitor is less than 4500 angstroms based on a surface of a substrate close to an anode.

### CROSS-REFERENCE TO RELATED APPLICATION

This application claims priority to and the benefit of Chinese Patent Application No. 202510122905.4, filed on January 24, 2025, the disclosure of which is incorporated herein by reference in its entirety.

### TECHNICAL FIELD

The present disclosure relates to the field of display, and in particular, to a display panel and a display device.

### BACKGROUND

For an organic light-emitting display panel prepared by inkjet printing, the flatness of the topography of the pixel opening region of the driving backplate determines the uniformity of film layers after curing of the ink. Based on the improvement of the resolution of the display panel, the area of a compensation capacitor is reduced, which may reduce the capacitance of the compensation capacitor. In addition, in order to improve the resolution of the display panel, a driving thin film transistor and the compensation capacitor are disposed in the pixel opening region, however, the topography of the driving thin film transistor and the topography of the compensation capacitor may affect the flatness of the pixel opening region.

### SUMMARY

Some embodiments of the present disclosure provide a display panel, including:

a substrate;

a first thin film transistor disposed on the substrate;

a capacitor disposed on the substrate and located at a side of the first thin film transistor;

an anode disposed on a side of the first thin film transistor as well as the capacitor away from the substrate; and

a pixel definition layer disposed on a side of the anode away from the substrate, where the pixel definition layer is provided with a pixel opening exposing the anode;

where both the first thin film transistor and the capacitor partially overlap the anode, the capacitor includes at least three electrode plates stacked and spaced apart, and a difference between a height of the first thin film transistor and a height of the capacitor is less than 4500 angstroms based on a surface of the substrate close to the anode.

Some embodiments of the present disclosure provide a display device including the display panel as described above.

### BRIEF DESCRIPTION OF THE DRAWINGS

FIG. 1 is a first schematic structural diagram of a display panel according to some embodiments of the present disclosure.

FIG. 2 is a schematic partial top view of the display panel according to some embodiments of the present disclosure.

FIG. 3 is a schematic top view of film layers where a light-shielding portion and a first electrode plate illustrated in FIG. 2 are located.

FIG. 4 is a schematic top view based on FIG. 3 in which film layers where a first active portion and a second electrode plate are located are added.

FIG. 5 is a schematic top view based on FIG. 4 in which a film layer where a first gate is located is added.

FIG. 6 is a schematic top view based on FIG. 5 in which a film layer where a third electrode plate is located is added.

FIG. 7 is a schematic top view based on FIG. 6 in which film layers where a first electrode, a second electrode, and an adapter portion are located is added.

FIG. 8 is a second schematic structural diagram of the display panel according to some embodiments of the disclosure.

FIG. 9 is a third schematic structural diagram of the display panel according to some embodiments of the disclosure.

FIG. 10 is a fourth schematic structural diagram of the display panel according to some embodiments of the disclosure.

FIG. 11 is a schematic structural diagram of a display device according to some embodiments of the present disclosure.

### DETAILED DESCRIPTION

The technical solutions in the embodiments of the present disclosure will be described clearly and completely hereafter with reference to the accompanying drawings. Apparently, the described embodiments are only a part of the embodiments of the present disclosure, but not all them. According to the embodiments of the present disclosure, all other embodiments obtained by those skilled in the art without making creative efforts shall fall within the scope of protection of the present disclosure. Furthermore, it should be understood that the specific embodiments described here are only for the purpose of illustration and explanation of the present disclosure and are not intended to limit the present disclosure. In the present disclosure, various embodiments may be combined with each other but will not be redundantly described here. Unless otherwise specified, the directional terms, such as “on”, “above”, and “below”, generally refer to upward and downward directions of the device, in actual use or working state, or in particular directions in the drawings; and terms “inside” and “outside” are relative to the contour of the devices shown in the drawings. The terms “first”, “second”, “third”, etc. are used for indicative purposes only and do not impose numerical requirements or establish order.

The embodiments of the present disclosure provide a display panel and a display device, which will be described in detail below. It should be noted that the order of description of the following embodiments is not intended to limit the preferred order of the embodiments.

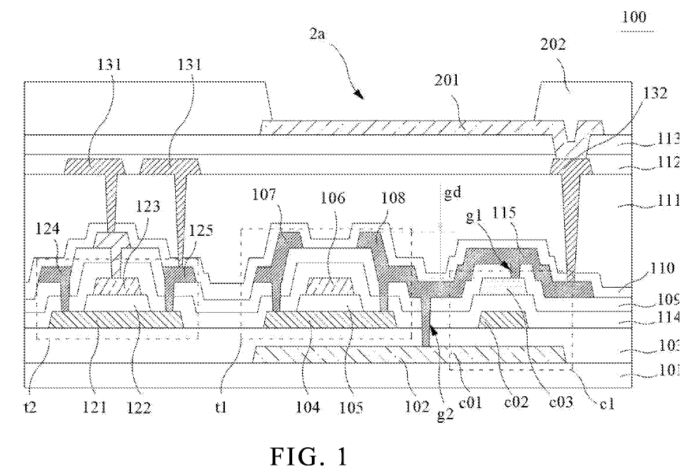

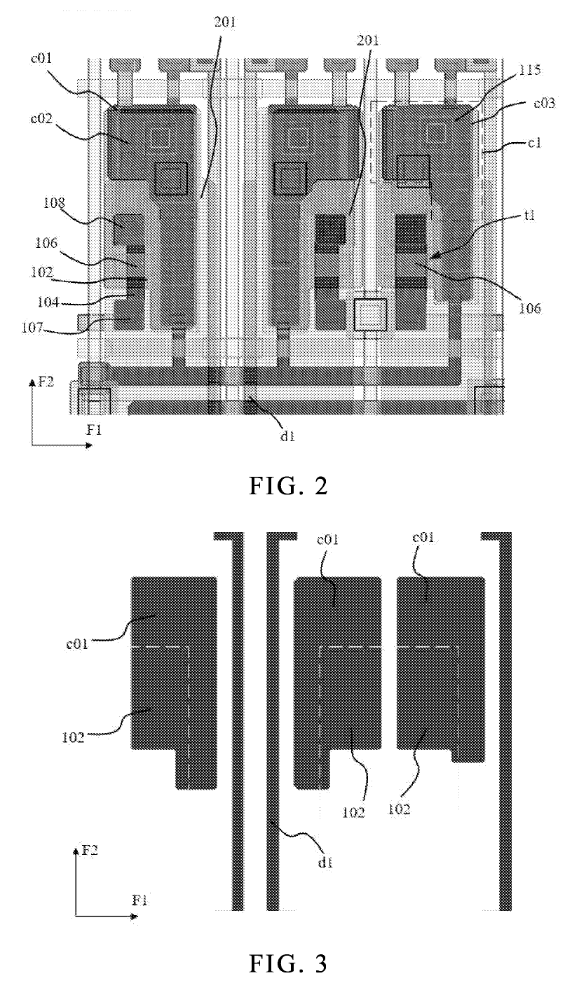

Referring to FIGS. 1 and 2, some embodiments of the present disclosure provide a display panel 100 that includes a substrate 101, a first thin film transistor t1, a capacitor c1, an anode 201, and a pixel definition layer 202.

The first thin film transistor t1 is disposed on the substrate 101. The capacitor c1 is disposed on the substrate 101 and located at a side of the first thin film transistor t1. The anode 201 is disposed on a side of the first thin film transistor t1 as well as the capacitor c1 away from the substrate 101. The pixel definition layer 202 is disposed on a side of the anode 201 away from the substrate 101 and provided with a pixel opening 2a exposing the anode 201.

The first thin film transistor t1 and the capacitor c1 overlap two parts of the anode 201, respectively. The capacitor c1 includes at least three electrode plates stacked and spaced apart. A difference gd between a height of the first thin film transistor t1 and a height of the capacitor c1 is less than 4500 angstroms based on a surface of the substrate 101 close to the anode 201.

The display panel 100 provided in the embodiment of the present disclosure includes the first thin film transistor t1 and the capacitor c1 disposed in a region where the pixel opening 2a is located. By providing at least three electrode plates, the present disclosure increases the capacitance of the capacitor c1 and elevates the topography of the region where the capacitor c1 is located. Moreover, the difference between the height of the first thin film transistor t1 and the height of the capacitor c1 is set to be less than 4500 angstroms, so that the topography of the first thin film transistor t1 and the topography of the capacitor c1 tend to be similar, thereby improving the flatness of the region where the pixel opening 2a is located.

The difference gd between the height of the first thin film transistor t1 and the height of the capacitor c1 in a thickness direction of the display panel 100 is less than 4500 angstroms. For example, the difference between the height of the first thin film transistor t1 and the height of the capacitor c1 may be 4400 angstroms, 4300 angstroms, 4200 angstroms, 4100 angstroms, 4000 angstroms, 3900 angstroms, 3800 angstroms, 3700 angstroms, 3600 angstroms, 3500 angstroms, 3400 angstroms, 3300 angstroms, 3200 angstroms, 3100 angstroms, 3000 angstroms, 2900 angstroms, 2800 angstroms, 2700 angstroms, 2600 angstroms, 2500 angstroms, 2400 angstroms, 2300 angstroms, 2200 angstroms, 2100 angstroms, 2000 angstroms, 1900 angstroms, 1800 angstroms, 1700 angstroms, 1600 angstroms, 1500 angstroms, 1400 angstroms, 1300 angstroms, 1200 angstroms, 1100 angstroms, 1000 angstroms, 900 angstroms, 800 angstroms, 700 angstroms, 600 angstroms, 500 angstroms, 400 angstroms, 300 angstroms, 200 angstroms, 100 angstroms, 90 angstroms, 80 angstroms, 70 angstroms, 60 angstroms, 50 angstroms, 40 angstroms, 30 angstroms, 20 angstroms, 10 angstroms, or 0 angstrom.

It can be understood that, the larger the number of the electrode plates included in the capacitor c1 is, the higher the topography of the capacitor c1 is, and the closer the topography of the capacitor c1 is to the topography of the first thin film transistor t1, so that the region where the pixel opening 2a is located has high flatness.

The first thin film transistor t1 may be served as a driving thin film transistor in a display region, and the first thin film transistor t1 is connected to the anode 201.

Alternatively, the display panel 100 further includes a light-emitting functional layer disposed on the anode 201. The light-emitting functional layer is composed of one or more of an emission layer, a hole injection layer, a hole transport layer, an electron transport layer, and an electron injection layer. When the light-emitting functional layer includes all of the above-mentioned layers, the hole injection layer may be disposed on the anode 201, and the hole transport layer, the emission layer, the electron transport layer, and the electron injection layer are sequentially stacked on the hole injection layer.

Alternatively, in some embodiments of the present disclosure, the display panel 100 further includes a light-shielding portion 102, a buffer layer 103, and an interlayer dielectric layer 109. The first thin film transistor t1 includes a first active portion 104, a first gate insulating portion 105, a first gate 106, a first electrode 107, and a second electrode 108. The capacitor c1 includes a first electrode plate c01, a second electrode plate c02, and a third electrode plate c03.

The first electrode plate c01 is disposed in the same layer as the light-shielding portion 102. The buffer layer 103 covers the first electrode plate c01 and the light-shielding portion 102. The second electrode plate c02 is disposed in the same layer as the first active portion 104. The first gate insulating portion 105 is disposed on a side of the first active portion 104 away from the substrate 101. The first gate 106 is disposed on a side of the first gate insulating portion 105 away from the substrate 101. The interlayer dielectric layer 109 covers the first gate 106 and the capacitor c1. The first electrode 107 and the second electrode 108 are disposed on a side of the interlayer dielectric layer 109 away from the substrate 101.

The third electrode plate c03 is disposed on a side of the first electrode plate c01 in the thickness direction of the display panel 100, and one of the first electrode plate c01 and the second electrode plate c02 that is farther from the third electrode plate c03 is electrically connected to the third electrode plate c03.

It can be understood that, due to a large thickness of conductive film layers of the first thin film transistor t1, the conductive film layers may affect the topography of the first thin film transistor t1. Therefore, the first electrode plate c01 is disposed in the same layer as the light-shielding portion 102, and the second electrode plate c02 is disposed in the same layer as the first active portion 104, so as to offset the topography difference between the two conductive film layers. Moreover, by providing the third electrode plate c03 in the capacitor c1 to offset the topography difference with the first gate 106 of the first thin film transistor t1, the topography difference between the first thin film transistor t1 and the capacitor c1 can be reduced to improve the flatness of the anode 201.

Alternatively, in some embodiments of the present disclosure, the display panel 100 further includes a first planarization layer 111 and a second planarization layer 112 that sequentially cover the first thin film transistor t1 and the capacitor c1, and the anode 201 is disposed on a side of the second planarization layer 112 away from the substrate 101.

It can be understood that, the planarization layer has a certain leveling property, and one planarization layer has an upper limit on the leveling of the topography because of the limitations of existing equipment and processes. Therefore, on a basis of setting the difference between the height of the first thin film transistor t1 and the height of the capacitor c1 to be less than 4500 angstroms, the embodiments of the present disclosure compensates for the difference between the height of the first thin film transistor t1 and the height of the capacitor c1 by providing the first planarization layer 111 and the second planarization layer 112, thereby improving the flatness of the region where the pixel opening 2a is located, and thus improving the flatness of the anode 201.

Alternatively, in some embodiments, the difference between the height of the first thin film transistor t1 and the height of the capacitor c1 is less than or equal to 2600 angstroms. On a basis of this design, the first planarization layer 111 and the second planarization layer 112 can offset the difference between the height of the first thin film transistor t1 and the height of the capacitor c1, further improving the flatness of the region where the pixel opening 2a is located, and further improving the flatness of the anode 201.

In some embodiments, the display panel 100 further includes a third planarization layer 113 disposed on a side of the second planarization layer 112 away from the substrate 101. It can be understood that, in the region where the pixel opening 2a is located, in addition to the first thin film transistor t1 and the capacitor c1, inorganic insulating layers are also provided in a stacked configuration. Since an inorganic stacked topography formed by stacking the inorganic insulating layers may be lower than the topography of the first thin film transistor t1, the first planarization layer 111 and the second planarization layer 112 cannot completely compensate for the difference between the height of the first thin film transistor t1 and the height of the inorganic stacked topography. Therefore, in the above-mentioned embodiments, the third planarization layer 113 is provided to further compensate for the difference between the height of the first thin film transistor t1 and the height of the inorganic stacked topography, which further improves the flatness of the region where the pixel opening 2a is located to improve the flatness of the anode 201.

Alternatively, the inorganic stacked topography includes the buffer layer 103 and the interlayer dielectric layer 109.

Alternatively, in some embodiments of the present disclosure, the display panel 100 further includes a first insulating layer 114 and an adapter portion 115. The first insulating layer 114 covers the first gate 106 and the second electrode plate c02. The third electrode plate c03 is disposed on a side of the first insulating layer 114 away from the substrate 101. The interlayer dielectric layer 109 covers the first insulating layer 114 and the third electrode plate c03. The adapter portion 115, the first electrode 107, and the second electrode 108 are disposed in the same layer. The adapter portion 115 is connected to the first electrode plate c01 and the third electrode plate c03.

It can be understood that, the third electrode plate c03 is disposed on a side of the second electrode plate c02 away from the substrate 101, so that the adapter portion 115 is closer to the third electrode plate c03 to reduce the depth of the via hole between the adapter portion 115 and the third electrode plate c03.

Alternatively, the adapter portion 115 is connected to the third electrode plate c03 through a first via hole g1, and the second electrode 108 is connected to the first active portion 104 through another first via hole g1. The adapter portion 115 is connected to the first electrode plate c01 through a second via hole g2.

Alternatively, a thickness of the first gate 106 is equal to a thickness of the third electrode plate c03, a thickness of the first active portion 104 is equal to a thickness of the second electrode plate c02, and a thickness of the light-shielding portion 102 is equal to a thickness of the first electrode plate c01, but are not limited thereto. For example, the thickness of the first gate 106 may be less than the thickness of the third electrode plate c03, the thickness of the first active portion 104 may be equal to the thickness of the second electrode plate c02, and the thickness of the light-shielding portion 102 may be equal to the thickness of the first electrode plate c01, which further reduce the difference between the height of the first thin film transistor t1 and the height of the capacitor c1.

Alternatively, in some embodiments, the light-shielding portion 102 and the first electrode plate c01 are prepared by using the same mask, and the second electrode plate c02 and the first active portion 104 are prepared by using the same mask.

Alternatively, referring to FIGS. 2 to 7, in some embodiments of the present disclosure, in a top view of the display panel 100, the light-shielding portion 102 is connected to the first electrode plate c01, and the second electrode plate c02 and the first active portion 104 are spaced apart. The second electrode plate c02 includes a first sub-portion c21 and a second sub-portion c22 connected to each other. The first sub-portion c21 extends in a first direction F1, and the second sub-portion c22 extends in a second direction F2 intersecting the first direction F1. The first sub-portion c21 is disposed at a side of the first active portion 104 in the second direction F2, and the second sub-portion c22 is disposed at a side of the first active portion 104 in the first direction F1. Both the first sub-portion c21 and the second sub-portion c22 overlap the first electrode plate c01.

Alternatively, the first direction F1 is perpendicular to the second direction F2, but is not limited thereto. For example, the first direction F1 and the second direction F2 intersect with each other but are not perpendicular. Alternatively, the second direction F2 refers to an extension direction of a data line d1.

It can be understood that, the light-shielding portion 102 and the first electrode plate c01 are connected to form a whole, which not only reduces the difficulty of preparing the light-shielding portion 102 and the first electrode plate c01, but also increases the layout area of the first electrode plate c01.

Moreover, the first sub-portion c21 and the second sub-portion c22 are connected to form a shape that semi-surrounds the first active portion 104, which increases an overlapping area between the second electrode plate c02 and the first electrode plate c01 in a limited space, thereby increasing the capacitance of the capacitor c1 and elevating the topography of the region where the pixel opening 2a is located, further improving the flatness of the region where the pixel opening 2a is located.

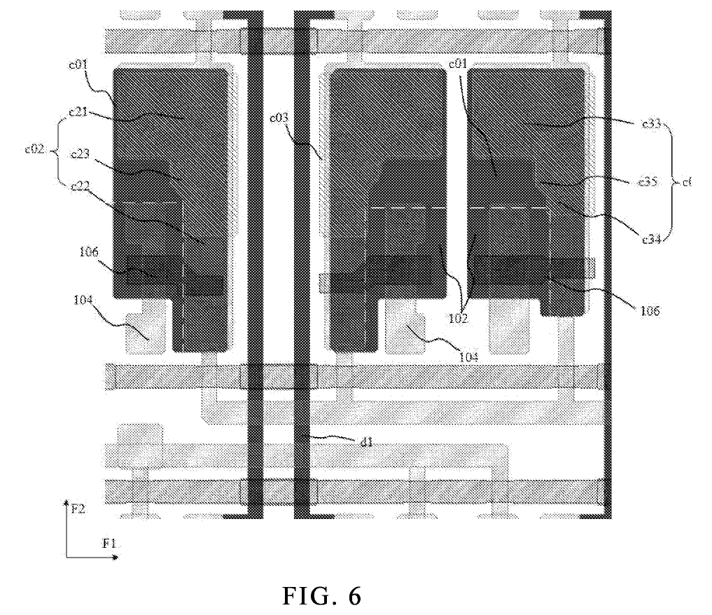

Alternatively, in some embodiments of the present disclosure, as illustrated in FIG. 6, in the top view of the display panel 100, the third electrode plate c03 includes a third sub-portion c33 and a fourth sub-portion c34 connected to each other, the third sub-portion c33 extends in the first direction F1, and the fourth sub-portion c34 extends in the second direction F2. The third sub-portion c33 overlaps the first sub-portion c21, and the fourth sub-portion c34 overlaps the second sub-portion c22.

It can be understood that, the third sub-portion c33 of the third electrode plate c03 overlaps the first sub-portion c21, and the fourth sub-portion c34 of the third electrode plate c03 overlaps the second sub-portion c22, so as to increase the overlapping area between the second electrode plate c02 and the third electrode plate c03 in a limited space, thereby increasing the capacitance of the capacitor c1 and elevating the topography of the region where the pixel opening 2a is located, further improving the flatness of the region where the pixel opening 2a is located.

Alternatively, in some embodiments of the present disclosure, in the top view of the display panel 100, the adapter portion 115 covers a part of the fourth sub-portion c34 and at least a part of the third sub-portion c33. The adapter portion 115 is connected to the second electrode 108.

In can be understood that, the adapter portion 115 covers a part of the third electrode plate c03, so as to reduce the impact of signal lines that are provided on a side of the capacitor c1 away from the substrate 101 on the capacitor c1. Moreover, the adapter portion 115 covers the third electrode plate c03 to elevate the topography of the region where the capacitor c1 is located, thereby reducing the difference between the height of the first thin film transistor t1 and the height of the capacitor c1, further improving the flatness of the region where the pixel opening 2a is located.

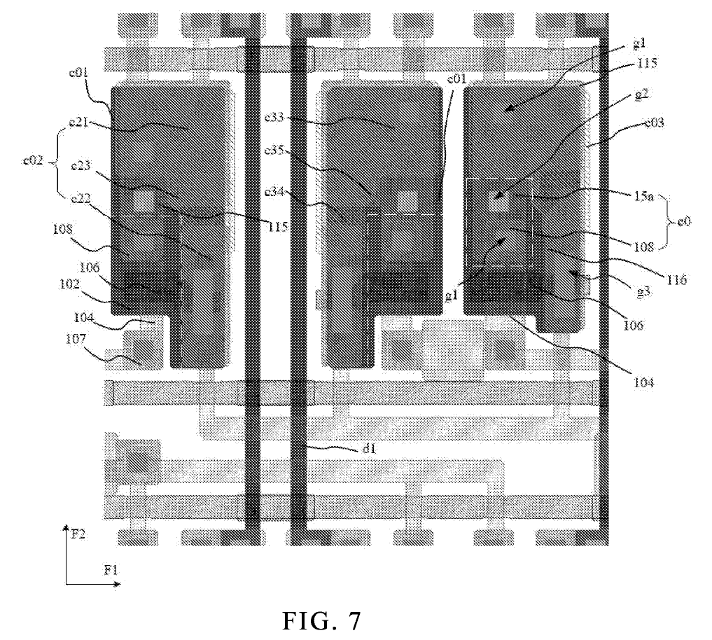

Alternatively, in some embodiments of the present disclosure, a part of the adapter portion 115 extends beyond the third electrode plate c03 and the second electrode plate c02. As illustrated in FIG. 7, an extension portion 15a of the adapter portion 115 is connected to the second electrode 108. The extension portion 15a of the adapter portion 115 is connected to the second electrode 108 to form a compensation electrode plate c04. The compensation electrode plate c04 partially overlaps the light-shielding portion 102 to form a compensation capacitor.

It can be understood that, by providing the compensation electrode plate c04 and the light-shielding portion 102 to form the compensation capacitor, the capacitance of the capacitor c1 can be increased and the topography of the region where the pixel opening 2a is located can be elevated, and thus the flatness of the region where the pixel opening 2a is located can be improved.

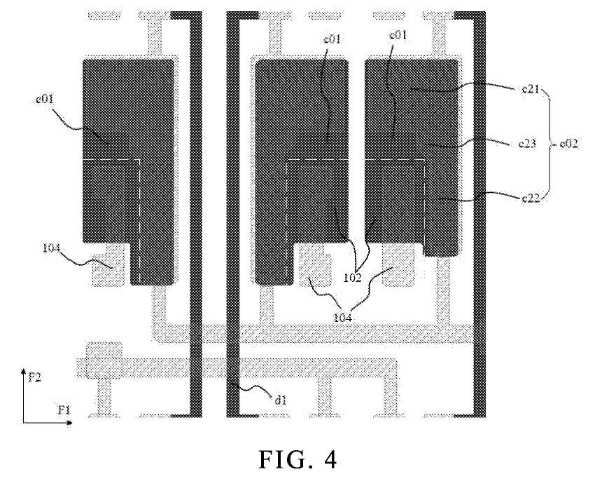

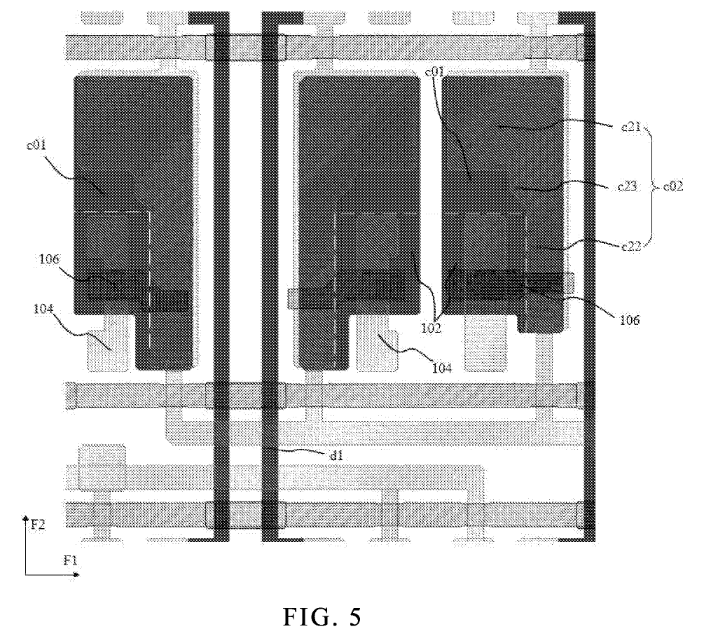

Alternatively, in some embodiments of the present disclosure, as illustrated in FIGS. 4 and 5, the second electrode plate c02 further includes a first convex portion c23 that is connected to the intersection of the first sub-portion c21 and the second sub-portion c22, and the first convex portion c23 is disposed close to the first active portion 104 and overlaps the first electrode plate c01. As illustrated in FIG. 6, the third electrode plate c03 further includes a second convex portion c35 that is connected to the intersection of the third sub-portion c33 and the fourth sub-portion c34, and the second convex portion c35 is disposed close to the first active portion 104 and overlaps the first convex portion c23.

It can be understood that, the setting of the first convex portion c23 and the second convex portion c35 can not only increase the capacitance of the capacitor c1, but also elevate the topography of the region where the pixel opening 2a is located, which further improve the flatness of the region where the pixel opening 2a is located.

Alternatively, in some embodiments, as illustrated in FIG. 7, the display panel 100 further includes a connecting portion 116 disposed in the same layer as the adapter portion 115 and spaced apart from the adapter portion 115. The connecting portion 116 is connected to the first gate 106 and the second electrode plate c02 through two third via holes g3, respectively.

Alternatively, in some embodiments of the present disclosure, the display panel 100 further includes a second thin film transistor t2 disposed in a gate driving circuit region. The second thin film transistor t2 includes a second active portion 121, a second gate insulating portion 122, a second gate 123, a third electrode 124, and a fourth electrode 125. The second active portion 121 is disposed on a side of the buffer layer 103 away from the substrate 101. The second gate insulating portion 122 is disposed on a side of the second active portion 121 away from the substrate 101. The second gate 123 is disposed on a side of the second gate insulating portion 122 away from the substrate 101. The first insulating layer 114 and the interlayer dielectric layer 109 sequentially cover the second gate 123. The third electrode 124 and the fourth electrode 125 are disposed on a side of the interlayer dielectric layer 109 away from the substrate 101.

Alternatively, the second active portion 121, the second electrode plate c02, and the first active portion 104 are disposed in the same layer and prepared by using the same mask. The second gate insulating portion 122 and the first gate insulating portion 105 are disposed in the same layer and prepared by using the same mask. The second gate 123 and the first gate 106 are disposed in the same layer and prepared by using the same mask. The third electrode 124, the fourth electrode 125, the first electrode 107, and the second electrode 108 are disposed in the same layer and prepared by using the same mask.

The display panel 100 further includes an outer peripheral wire 131 disposed in the gate driving circuit region. The outer peripheral wire 131 is disposed on a side of the second thin film transistor t2 away from the substrate 101. The outer peripheral wire 131 is electrically connected to the second thin film transistor t2.

Alternatively, the display panel 100 further includes a passivation layer 110 covering the first electrode 107, the second electrode 108, the third electrode 124, and the fourth electrode 125. The first planarization layer 111 covers the passivation layer 110. The outer peripheral wire 131 is disposed on a side of the first planarization layer 111 away from the substrate 101. The second planarization layer 112 covers the outer peripheral wire 131 and the first planarization layer 111.

The outer peripheral wire 131 is disposed in the gate driving circuit region to reduce the width of the bezel of the display panel 100. The number of outer peripheral wires 131 may be two, one outer peripheral wire 131 is connected to the second gate 123, and another outer peripheral wire 131 is connected to the fourth electrode 125.

Alternatively, one outer peripheral wire 131 connected to the second gate 123 is a clock signal line, and another outer peripheral wire 131 connected to the fourth electrode 125 is a power line or a reset signal line.

Alternatively, the display panel 100 further includes a wire-changing portion 132 disposed in the display region. The wire-changing portion 132 and the outer peripheral wire 131 are disposed in the same layer and on a side of the first planarization layer 111 away from the substrate 101. The second electrode 108 of the first thin film transistor t1 is connected to the anode 201 through the wire-changing portion 132.

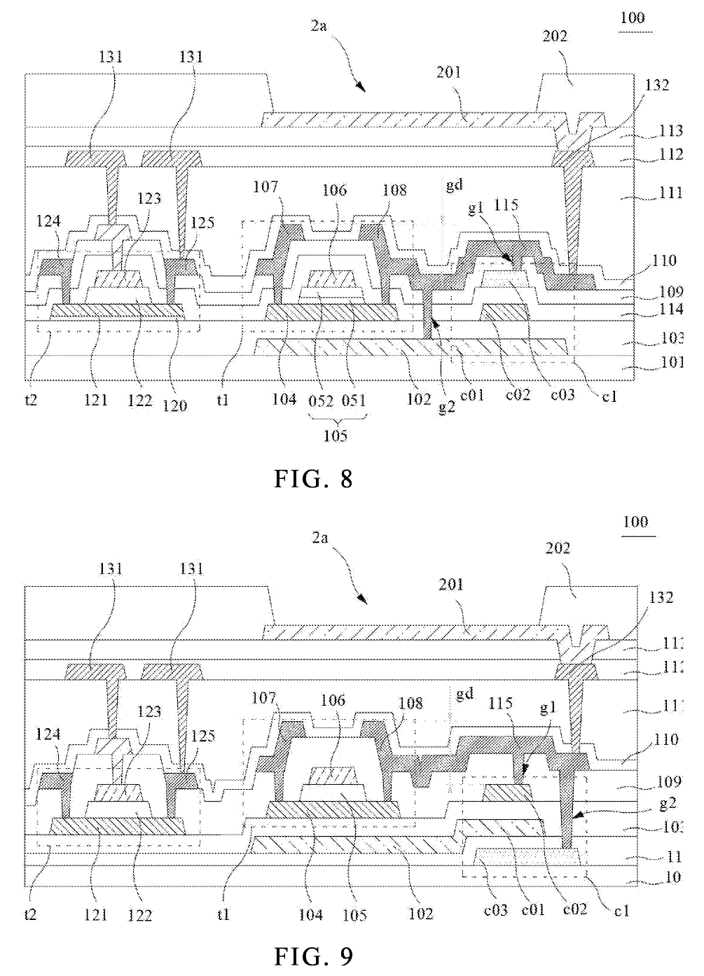

FIG. 8 illustrates a second schematic structural diagram of the display panel 100 according to some embodiments of the present disclosure. Differences between the display panel 100 illustrated in FIG. 8 and the display panel 100 illustrated in FIG. 1 will be described below.

In the display panel 100 illustrated in FIG. 8, the first gate insulating portion 105 includes a first sublayer 051 and a second sublayer 052 disposed in a stacked configuration, the second thin film transistor t 2 further includes a protective portion 120 disposed on a side of the buffer layer 103 away from the substrate 101, and the second active portion 121 is disposed on a side of the protective portion 120 away from the substrate 101. A carrier mobility of the first thin film transistor t1 is less than a carrier mobility of the second thin film transistor t2.

Alternatively, the first sublayer 051 and the protective portion 120 are prepared by the same mask and have the same material and the same thickness. The second sublayer 052 and the second gate insulating portion 122 are prepared by the same mask and have the same material and the same thickness.

FIG. 9 illustrates a third schematic structural diagram of the display panel 100 according to some embodiments of the present disclosure. Differences between the display panel 100 illustrated in FIG. 9 and the display panel 100 illustrated in FIG. 1 will be described below.

Compared with the display panel 100 illustrated in FIG. 1, in the display panel 100 illustrated in FIG. 9, the third electrode plate c03 is disposed on a side of the first electrode plate c01 close to the substrate 101, so as to save the wiring space above the second electrode plate c02 and facilitate the wiring layout. That is, the display panel 100 illustrated in FIG. 9 is formed by transferring the film layer where the third electrode plate c03 in FIG. 1 is located to a side of the film layer where the light-shielding portion 102 is located close to the substrate 101.

Alternatively, the third electrode plate c03 is a black electrode plate to enhance the overall black effect.

It should be noted that, in the top view of the display panel 100, the structures of the light-shielding portion 102, the first electrode plate c01, the second electrode plate c02, the third electrode plate c03, and the adapter portion 115 of the display panel 100 illustrated in FIG. 9 are similar to the structures of the light-shielding portion 102, the first electrode plate c01, the second electrode plate c02, the third electrode plate c03, and the adapter portion 115 of the display panel 100 illustrated in FIG. 1, respectively. The display panel 100 illustrated in FIG. 9 differs from the display panel 100 illustrated in FIG. 1 in that the first electrode plate c01 is spaced between the third electrode plate c03 and the second electrode plate c02, and both the third electrode plate c03 and the second electrode plate c02 overlap the first electrode plate c01 to form the capacitor c1. Moreover, on a basis of the third electrode plate c03 disposed below the first electrode plate c01, the display panel 100 illustrated in FIG. 9 further differs from the display panel 100 illustrated in FIG. 1 in that the third electrode plate c03 includes a contact portion extending beyond the first electrode plate c01 and connected to the adapter portion 115. The first electrode plate c01 is electrically connected to the first gate 106.

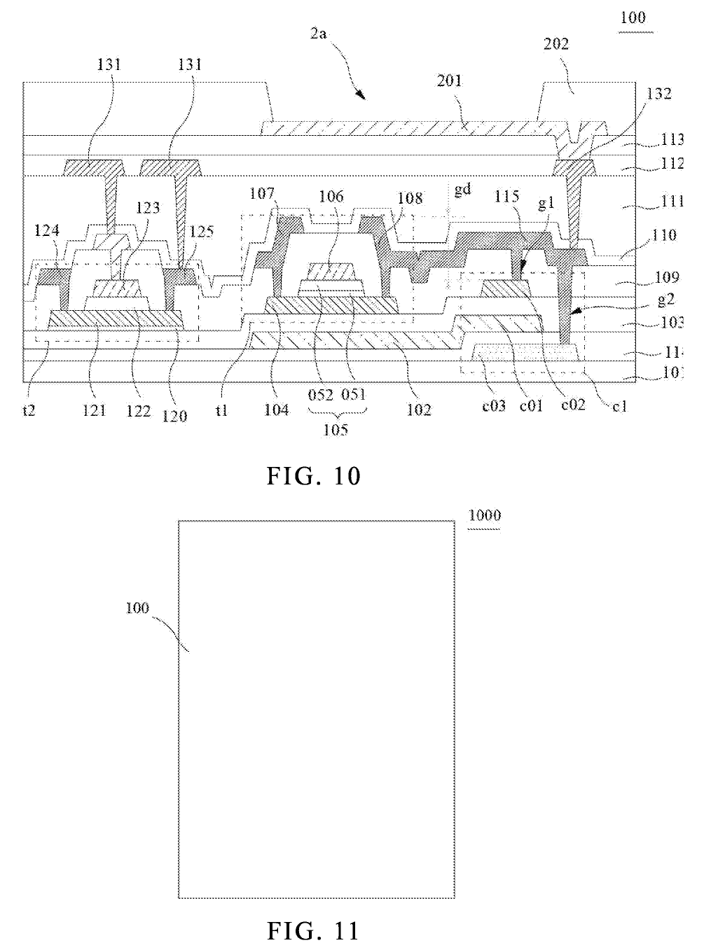

FIG. 10 illustrates a fourth schematic structural diagram of the display panel 100 according to some embodiments of the present disclosure. Differences between the display panel 100 illustrated in FIG. 10 and the display panel 100 illustrated in FIG. 9 will be described below.

In the display panel 100 illustrated in FIG. 10, the first gate insulating portion 105 includes a first sublayer 051 and a second sublayer 052 disposed in a stacked configuration, the second thin film transistor t2 further includes a protective portion 120 disposed on a side of the buffer layer 103 away from the substrate 101, and the second active portion 121 is disposed on a side of the protective portion 120 away from the substrate 101. A carrier mobility of the first thin film transistor t1 is less than a carrier mobility of the second thin film transistor t2.

Alternatively, the first sublayer 051 and the protective portion 120 are prepared by the same mask and have the same material and the same thickness. The second sublayer 152 and the second gate insulating portion 122 are prepared by the same mask and have the same material and the same thickness.

Referring to FIG. 11, some embodiments of the present disclosure provide a display device 1000 including the display panel 100 as described in any one of the above-mentioned embodiments.

The display panel 100 of the display device 1000 provided in the embodiments of the present disclosure includes the first thin film transistor t1 and the capacitor c1 disposed in the region where the pixel opening 2a is located, and the capacitor c1 includes at least three electrode plates stacked and spaced apart. The difference between the height of the first thin film transistor t1 and the height of the capacitor c1 is less than 4500 angstroms based on the surface of the substrate 101 close to the anode 201. By providing at least three electrode plates, the present disclosure increases the capacitance of the capacitor c1 and elevates the topography of the region where the capacitor c1 is located, so that the topography of the first thin film transistor t1 and the topography of the capacitor c1 tend to be similar, thereby improving the flatness of the region where the pixel opening 2a is located.

The above provides a detailed introduction to the display panel and the display device provided in the embodiments of the present disclosure. Specific embodiments are applied in this context to explain the principles and implementation methods of the present disclosure. The explanation of the above-mentioned embodiments is only used to help understand the technical solutions and core ideas of the present disclosure. For ordinary skilled in the art, there may be changes in the specific implementation methods and application scopes based on the ideas of the present disclosure. Therefore, the contents of the present disclosure should not be understood as limitations on the present disclosure.

What is claimed is:

1. A display panel, comprising:
a substrate;
a first thin film transistor disposed on the substrate;
a capacitor disposed on the substrate and located at a side of the first thin film transistor;
an anode disposed on a side of the first thin film transistor as well as the capacitor away from the substrate; and
a pixel definition layer disposed on a side of the anode away from the substrate, wherein the pixel definition layer is provided with a pixel opening exposing the anode;
wherein both the first thin film transistor and the capacitor partially overlap the anode, the capacitor comprises at least three electrode plates stacked and spaced apart, and a difference between a height of the first thin film transistor and a height of the capacitor is less than 4500 angstroms based on a surface of the substrate close to the anode.

2. The display panel according to claim 1, further comprising a light-shielding portion, a buffer layer, and an interlayer dielectric layer, wherein the first thin film transistor comprises a first active portion, a first gate insulating portion, a first gate, a first electrode, and a second electrode, and the capacitor comprises a first electrode plate, a second electrode plate, and a third electrode plate;
wherein the first electrode plate is disposed in a same layer as the light-shielding portion, the buffer layer covers the first electrode plate and the light-shielding portion, the second electrode plate is disposed in a same layer as the first active portion, the first gate insulating portion is disposed on a side of the first active portion away from the substrate, the first gate is disposed on a side of the first gate insulating portion away from the substrate, the interlayer dielectric layer covers the first gate and the capacitor, and the first electrode and the second electrode are disposed on a side of the interlayer dielectric layer away from the substrate; and
wherein the third electrode plate is disposed on a side of the first electrode plate in a thickness direction of the display panel, and one of the first electrode plate and the second electrode plate farther from the third electrode plate is electrically connected to the third electrode plate.

3. The display panel according to claim 2, further comprising a first insulating layer and an adapter portion, wherein the first insulating layer covers the first gate and the second electrode plate, the third electrode plate is disposed on a side of the first insulating layer away from the substrate, the interlayer dielectric layer covers the first insulating layer and the third electrode plate, the adapter portion, the first electrode, and the second electrode are disposed in a same layer, and the adapter portion is connected to the first electrode plate and the third electrode plate.

4. The display panel according to claim 3, wherein in a top view of the display panel, the light-shielding portion is connected to the first electrode plate, the second electrode plate and the first active portion are spaced apart, the second electrode plate comprises a first sub-portion and a second sub-portion connected to each other, the first sub-portion extends in a first direction, the second sub-portion extends in a second direction intersecting the first direction, the first sub-portion is disposed at a side of the first active portion in the second direction, the second sub-portion is disposed at a side of the first active portion in the first direction, and both the first sub-portion and the second sub-portion overlap the first electrode plate.

5. The display panel according to claim 4, wherein in the top view of the display panel, the third electrode plate comprises a third sub-portion and a fourth sub-portion connected to each other, the third sub-portion extends in the first direction and overlaps the first sub-portion, and the fourth sub-portion extends in the second direction and overlaps the second sub-portion.

6. The display panel according to claim 5, wherein in the top view of the display panel, the adapter portion covers a part of the fourth sub-portion and at least a part of the third sub-portion, and the adapter portion is connected to the second electrode.

7. The display panel according to claim 3, further comprising a second thin film transistor disposed in a gate driving circuit region, wherein the second thin film transistor comprises a second active portion, a second gate insulating portion, a second gate, a third electrode, and a fourth electrode, the second active portion is disposed on a side of the buffer layer away from the substrate, the second gate insulating portion is disposed on a side of the second active portion away from the substrate, the second gate is disposed on a side of the second gate insulating portion away from the substrate, the first insulating layer and the interlayer dielectric layer sequentially cover the second gate, and the third electrode and the fourth electrode are disposed on a side of the interlayer dielectric layer away from the substrate; and
wherein the display panel further comprises an outer peripheral wire disposed in the gate driving circuit region, and the outer peripheral wire is disposed on a side of the second thin film transistor away from the substrate and electrically connected to the second thin film transistor.

8. The display panel according to claim 3, wherein the first gate insulating portion comprises a first sublayer and a second sublayer disposed in a stacked configuration;
wherein the display panel further comprises a second thin film transistor disposed in a gate driving circuit region, the second thin film transistor comprises a protective portion, a second active portion, a second gate insulating portion, a second gate, a third electrode, and a fourth electrode, the protective portion is disposed on a side of the buffer layer away from the substrate, the second active portion is disposed on a side of the protective portion away from the substrate, the second gate insulating portion is disposed on a side of the second active portion away from the substrate, the second gate is disposed on a side of the second gate insulating portion away from the substrate, the first insulating layer and the interlayer dielectric layer sequentially cover the second gate, and the third electrode and the fourth electrode are disposed on a side of the interlayer dielectric layer away from the substrate; and
wherein the display panel further comprises an outer peripheral wire disposed in the gate driving circuit region, and the outer peripheral wire is disposed on a side of the second thin film transistor away from the substrate and electrically connected to the second thin film transistor.

9. The display panel according to claim 2, further comprising a first insulating layer and an adapter portion, wherein the third electrode plate is disposed on a side of the first electrode plate close to the substrate, the first insulating layer covers the third electrode plate and the substrate, the buffer layer covers the first insulating layer, the adapter portion and the first electrode are disposed in a same layer and on a side of the interlayer dielectric layer away from the substrate, and the adapter portion is connected to the second electrode plate and the third electrode plate.

10. The display panel according to claim 9, further comprising a second thin film transistor disposed in a gate driving circuit region, wherein the second thin film transistor comprises a second active portion, a second gate insulating portion, a second gate, a third electrode, and a fourth electrode, the second active portion is disposed on a side of the buffer layer away from the substrate, the second gate insulating portion is disposed on a side of the second active portion away from the substrate, the second gate is disposed on a side of the second gate insulating portion away from the substrate, the first insulating layer and the interlayer dielectric layer sequentially cover the second gate, and the third electrode and the fourth electrode are disposed on a side of the interlayer dielectric layer away from the substrate; and
wherein the display panel further comprises an outer peripheral wire disposed in the gate driving circuit region, and the outer peripheral wire is disposed on a side of the second thin film transistor away from the substrate and electrically connected to the second thin film transistor.

11. The display panel according to claim 9, wherein the first gate insulating portion comprises a first sublayer and a second sublayer disposed in a stacked configuration;
wherein the display panel further comprises a second thin film transistor disposed in a gate driving circuit region, the second thin film transistor comprises a protective portion, a second active portion, a second gate insulating portion, a second gate, a third electrode, and a fourth electrode, the protective portion is disposed on a side of the buffer layer away from the substrate, the second active portion is disposed on a side of the protective portion away from the substrate, the second gate insulating portion is disposed on a side of the second active portion away from the substrate, the second gate is disposed on a side of the second gate insulating portion away from the substrate, the interlayer dielectric layer covers the second gate, and the third electrode and the fourth electrode are disposed on a side of the interlayer dielectric layer away from the substrate; and
wherein the display panel further comprises an outer peripheral wire disposed in the gate driving circuit region, and the outer peripheral wire is disposed on a side of the second thin film transistor away from the substrate and electrically connected to the second thin film transistor.

12. The display panel according to claim 1, further comprising a first planarization layer and a second planarization layer sequentially covering the first thin film transistor and the capacitor, wherein the anode is disposed on a side of the second planarization layer away from the substrate.

13. A display device comprising a display panel, wherein the display panel comprises:
a substrate;
a first thin film transistor disposed on the substrate;
a capacitor disposed on the substrate and located on a side of the first thin film transistor;
an anode disposed on a side of the first thin film transistor as well as the capacitor away from the substrate; and
a pixel definition layer disposed on a side of the anode away from the substrate, wherein the pixel definition layer is provided with a pixel opening exposing the anode;
wherein both the first thin film transistor and the capacitor partially overlap the anode, the capacitor comprises at least three electrode plates stacked and spaced apart, and a difference between a height of the first thin film transistor and a height of the capacitor is less than 4500 angstroms based on a surface of the substrate close to the anode.

14. The display device according to claim 13, wherein the display panel further comprises a light-shielding portion, a buffer layer, and an interlayer dielectric layer, the first thin film transistor comprises a first active portion, a first gate insulating portion, a first gate, a first electrode, and a second electrode, and the capacitor comprises a first electrode plate, a second electrode plate, and a third electrode plate;
wherein the first electrode plate is disposed in a same layer as the light-shielding portion, the buffer layer covers the first electrode plate and the light-shielding portion, the second electrode plate is disposed in a same layer as the first active portion, the first gate insulating portion is disposed on a side of the first active portion away from the substrate, the first gate is disposed on a side of the first gate insulating portion away from the substrate, the interlayer dielectric layer covers the first gate and the capacitor, and the first electrode and the second electrode are disposed on a side of the interlayer dielectric layer away from the substrate; and
wherein the third electrode plate is disposed on a side of the first electrode plate in a thickness direction of the display panel, and one of the first electrode plate and the second electrode plate farther from the third electrode plate is electrically connected to the third electrode plate.

15. The display device according to claim 14, wherein the display panel further comprises a first insulating layer and an adapter portion, the first insulating layer covers the first gate and the second electrode plate, the third electrode plate is disposed on a side of the first insulating layer away from the substrate, the interlayer dielectric layer covers the first insulating layer and the third electrode plate, the adapter portion, the first electrode, and the second electrode are disposed in a same layer, and the adapter portion is connected to the first electrode plate and the third electrode plate.

16. The display device according to claim 15, wherein in a top view of the display panel, the light-shielding portion is connected to the first electrode plate, the second electrode plate and the first active portion are spaced apart, the second electrode plate comprises a first sub-portion and a second sub-portion connected to each other, the first sub-portion extends in a first direction, the second sub-portion extends in a second direction intersecting the first direction, the first sub-portion is disposed at a side of the first active portion in the second direction, the second sub-portion is disposed at a side of the first active portion in the first direction, and both the first sub-portion and the second sub-portion overlap the first electrode plate.

17. The display device according to claim 16, wherein in the top view of the display panel, the third electrode plate comprises a third sub-portion and a fourth sub-portion connected to each other, the third sub-portion extends in the first direction and overlaps the first sub-portion, and the fourth sub-portion extends in the second direction and overlaps the second sub-portion.

18. The display device according to claim 17, wherein in the top view of the display panel, the adapter portion covers a part of the fourth sub-portion and at least a part of the third sub-portion, and the adapter portion is connected to the second electrode.

19. The display device according to claim 15, wherein the first gate insulating portion comprises a first sublayer and a second sublayer disposed in a stacked configuration;
wherein the display panel further comprises a second thin film transistor disposed in a gate driving circuit region, the second thin film transistor comprises a protective portion, a second active portion, a second gate insulating portion, a second gate, a third electrode, and a fourth electrode, the protective portion is disposed on a side of the buffer layer away from the substrate, the second active portion is disposed on a side of the protective portion away from the substrate, the second gate insulating portion is disposed on a side of the second active portion away from the substrate, the second gate is disposed on a side of the second gate insulating portion away from the substrate, the first insulating layer and the interlayer dielectric layer sequentially cover the second gate, and the third electrode and the fourth electrode are disposed on a side of the interlayer dielectric layer away from the substrate; and
wherein the display panel further comprises an outer peripheral wire disposed in the gate driving circuit region, and the outer peripheral wire is disposed on a side of the second thin film transistor away from the substrate and electrically connected to the second thin film transistor.

20. The display device according to claim 14, wherein the display panel further comprises a first insulating layer and an adapter portion, the third electrode plate is disposed on a side of the first electrode plate close to the substrate, the first insulating layer covers the third electrode plate and the substrate, the buffer layer covers the first insulating layer, the adapter portion and the first electrode are disposed in a same layer and on a side of the interlayer dielectric layer away from the substrate, and the adapter portion is connected to the second electrode plate and the third electrode plate.
